(19) United States
(12) Patent Application Publication
(10) Pub. No.: US 2026/0114225 A1
(43) Pub. Date: Apr. 23, 2026

(54) SEMICONDUCTOR MANUFACTURING EQUIPMENT

(71) Applicant: Samsung Electronics Co., Ltd., Suwon-si (KR)

(72) Inventors: Ikkyun Yim, Suwon-si (KR); Hyeokjae Kwon, Suwon-si (KR); Kideok Hwang, Suwon-si (KR); Euiseok Kum, Suwon-si (KR); Byeonghee Kim, Suwon-si (KR)

(21) Appl. No.: 19/345,690

(22) Filed: Sep. 30, 2025

(30) Foreign Application Priority Data
Oct. 17, 2024 (KR) 10-2024-0142310

(51) Int. Cl. H01L 21/677; H01L 21/67

(52) U.S. Cl. CPC H10P 72/3218; H10P 72/0454; H10P 72/0602; H10P 72/0604; H10P 72/3411

(57) ABSTRACT

Semiconductor manufacturing equipment includes a substrate supply unit to which a front opening unified pod (FOUP) is detachably coupled and accommodates a first substrate therein, a process chamber in which a process is performed on a second substrate, a stage provided between the process chamber and the substrate supply unit, the stage including a cooler configured to cool a third substrate and a transfer robot configured to transfer the substrates, and a control unit configured to control the transfer robot by comparing first time data with second time data, the first time data being an amount of time taken for the transfer robot to transfer the third substrate from the cooler to the substrate supply unit, and the second time data being an amount of time remaining before completion of the process performed in the process chamber.

### CROSS-REFERENCE TO RELATED APPLICATION

This application is based on and claims priority under 35 U.S.C. § 119 to Korean Patent Application No. 10-2024-0142310, filed on Oct. 17, 2024, in the Korean Intellectual Property Office, the disclosure of which is incorporated by reference herein in its entirety.

### BACKGROUND

Conventional semiconductor manufacturing equipment may include a process chamber for performing a process treatment on a semiconductor substrate, and a cooler for cooling the semiconductor substrate after the process treatment has been completed.

Using conventional semiconductor manufacturing equipment, processing in the process chamber may be completed while a transfer robot is transferring a cooled substrate from the cooler to a supply unit. In this case, there may be an undesirable delay between the completion of the processing in the process chamber and the beginning of subsequent processing in the process chamber, while the transfer robot transfers the cooled substrate to the supply unit. It may therefore be desirable to reduce or eliminate the undesirable delay between processes in the processing chamber.

### SUMMARY

Aspects of the inventive concept relate to semiconductor manufacturing equipment including a process chamber for performing a process treatment on a semiconductor substrate, and a cooler for cooling the semiconductor substrate after the process treatment has been completed.

According to aspects of the inventive concept, the semiconductor manufacturing equipment may use a scheduler to manage working hours of a transfer robot and a processing unit for process operations according to a substrate processing recipe, that is, by a plurality of process operations. A substrate supplied from a load port may be put into a process chamber where it is processed, and the processed substrate in the process chamber may be cooled in a cooler. The processes described above may be repeated. To make the process more efficient, if none of the substrates in the process chamber have been completely processed, the transfer robot may skip the operation of unloading the substrate from the process chamber and may instead immediately unload the cooled substrate from the cooler.

Aspects of the inventive concept provide semiconductor manufacturing equipment having improved process efficiency.

The technical tasks of the inventive concept are not limited to the technical tasks mentioned above, and other technical tasks not mentioned will be clearly understood by those skilled in the art from the following description.

According to an aspect of the inventive concept, semiconductor manufacturing equipment includes a substrate supply unit to which a front opening unified pod (FOUP) is configured to be detachably coupled, wherein the FOUP is configured to accommodate a first substrate therein; a process chamber configured to perform a process on a second substrate transferred from the substrate supply unit; a stage provided between the process chamber and the substrate supply unit, the stage including a cooler and a transfer robot, the cooler being configured to cool the a third substrate on which the process has been completed in the process chamber, the transfer robot being configured to transfer the first substrate, the second substrate, and the third substrate while moving in and out of the substrate supply unit, the process chamber, and the cooler; and a control unit configured to control the transfer robot by comparing first time data with second time data after the transfer robot receives the first substrate from the substrate supply unit, the first time data being an amount of time taken for the transfer robot to transfer the third substrate from the cooler to the substrate supply unit, and the second time data being an amount of time remaining before completion of the process performed on the second substrate in the process chamber.

According to another aspect of the inventive concept, semiconductor manufacturing equipment includes a substrate supply unit to which a front opening unified pod (FOUP) is configured to be detachably coupled, wherein a substrate is accommodated in the FOUP is configured to accommodate a first substrate therein; a process chamber in which configured to perform a process is performed on the a second substrate transferred from the substrate supply unit; a stage provided between the process chamber and the substrate supply unit; a cooler within the stage, the cooler being configured to cool the a third substrate on which the process has been completed in the process chamber within the stage; a transfer robot configured to wait in the stage to transfer the first substrate, the second substrate, and the third substrate while moving in and out of the substrate supply, the process chamber, and the cooler; and a control unit configured to control operation of the transfer robot by comparing first time data, which is time data with second time data after the transfer robot receives the first substrate from the substrate supply unit, the first time data being an amount of time taken for the transfer robot waiting in the stage to transfer the third substrate in from the cooler to the substrate supply unit, with second time data, which is and the second time data being an amount of time remaining process time data of before completion of the process performed on the second substrate in the process chamber, after the transfer robot receives the substrate from the substrate supply unit.

According to another aspect of the inventive concept, semiconductor manufacturing equipment includes a substrate supply unit including a front opening unified pod (FOUP) and a load port, the FOUP being configured to accommodate in which a first substrate is accommodated and, the a load port to which the FOUP is being detachably coupled to the FOUP; a process chamber in which configured to perform a process is performed on the a second substrate transferred from the substrate supply unit; a cooler configured to cool the a third substrate on which the process has been completed in the process chamber; a stage accommodating the cooler and communicating connected with the process chamber; an equipment front end module (EFEM) positioned between the stage and the load port and including an end effector configured to transfer the first substrate accommodated in the FOUP to the stage or to transfer, to the FOUP, the third substrate on which the process has been completed in the process chamber; a transfer robot configured to wait in the stage to transfer the first substrate, the second substrate, and the third substrate while moving in and out of the EFEM, the process chamber, and the cooler; and a control unit configured to control operation of the transfer robot by comparing first time data, which is time data with second time data after the transfer robot receives the first substrate from the EFEM, the first time data being an amount of time taken for the transfer robot waiting in the stage to transfer the third substrate in from the cooler to the EFEM, with second time data, which is and the second time data being an amount of time remaining process time data of before completion of the process performed on the second substrate in the process chamber, after the transfer robot receives the substrate from the EFEM.

According to another aspect of the inventive concept, a method of manufacturing a semiconductor device uses semiconductor manufacturing equipment, in a state in which a first substrate is positioned in a substrate supply unit, a second substrate is being processed in a process chamber, and a third substrate is being cooled in a cooler, the method including acquiring, by a control unit, first time data and second time data, the first time data being an amount of time taken for a transfer robot to transfer the third substrate that is being cooled in the cooler to the substrate supply unit, and the second time data being an amount of time remaining before completion of a process performed on the second substrate by the process chamber; comparing the first time data with the second time data; and controlling the transfer robot based on the comparison of the first time data with the second time data.

According to another aspect of the inventive concept, a method of manufacturing a semiconductor device includes positioning a first substrate in a substrate supply unit; performing a process on a second substrate positioned in a process chamber; cooling a third substrate positioned in a cooler; unloading the first substrate from the substrate supply unit using a transfer robot; and controlling the transfer robot to move at least one of the first substrate, the second substrate, and the third substrate by comparing first time data with second time data after the transfer robot receives the first substrate from the substrate supply unit, the first time data being an amount of time taken for the transfer robot to transfer the third substrate from the cooler to the substrate supply unit, and the second time data being an amount of time remaining before completion of the process performed on the second substrate in the process chamber.

### BRIEF DESCRIPTION OF THE DRAWINGS

Embodiments will be more clearly understood from the following detailed description taken in conjunction with the accompanying drawings in which:

FIG. 1 is a plan view of semiconductor manufacturing equipment according to an embodiment;

FIG. 2 is a block diagram schematically illustrating a system configuration of a semiconductor manufacturing equipment according to an embodiment;

FIG. 3 is a flowchart illustrating a method of controlling semiconductor manufacturing equipment according to an embodiment;

FIG. 4 is a flowchart of a portion of the method of controlling the semiconductor manufacturing equipment shown in FIG. 3;

FIGS. 5 to 10 are diagrams sequentially illustrating a method of controlling semiconductor manufacturing equipment according to an embodiment, in time series order; and

FIGS. 11 to 13 are diagrams sequentially illustrating a process of a portion of a method of controlling semiconductor manufacturing equipment according to an embodiment, in time series order.

### DETAILED DESCRIPTION OF THE EMBODIMENTS

Embodiments of the inventive concept are now described in detail with reference to the accompanying drawings. Like reference numerals refer to like elements in the drawings, and redundant descriptions thereof are omitted.

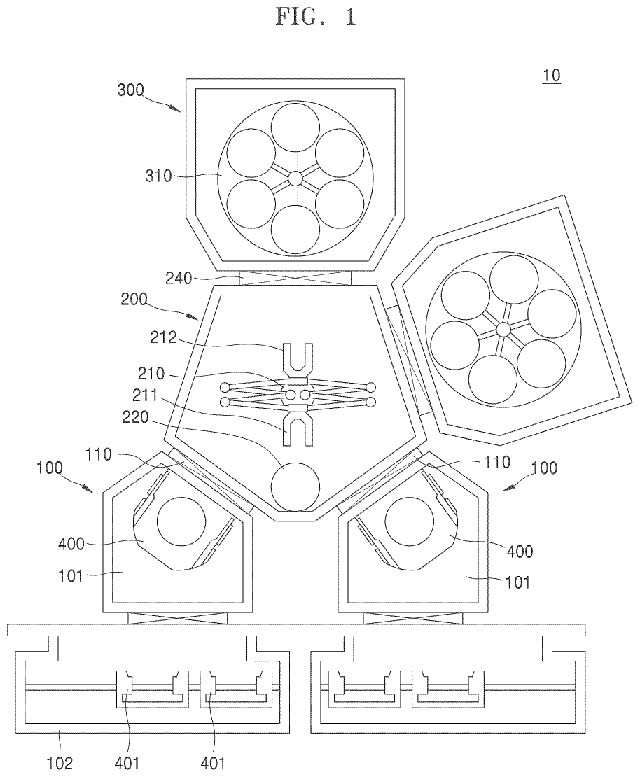

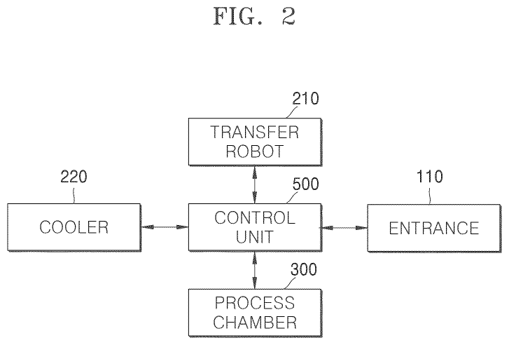

FIG. 1 is a plan view of semiconductor manufacturing equipment 10 according to an embodiment, and FIG. 2 is a block diagram schematically illustrating a system configuration of a semiconductor manufacturing equipment 10 according to an embodiment.

Referring to FIGS. 1 and 2, semiconductor manufacturing equipment 10 may include a substrate supply unit 100, a stage 200, a process chamber 300, a front opening unified pod (FOUP) 400, and a control unit 500.

According to an embodiment, the substrate supply unit 100 may include a load port 101, an entrance 110, and a FOUP loading unit 102.

The semiconductor manufacturing equipment 10 may be configured to perform various processes on a substrate. The semiconductor manufacturing equipment 10 may include a process chamber 300 in which processing on the substrate is performed, a stage 200 supporting the process chamber 300, a load port 101 configured to supply the substrate to the stage 200, a FOUP 400 in which the substrate is loaded and which is detachably seated in the load port 101, and extra FOUPs 401 waiting in the FOUP loading unit 102.

The substrate supply unit 100 may include the load port 101 coupled to the front end of the stage 200 to bring the substrate into or out of the stage 200, a FOUP 400 in which the substrate is loaded and which is detachably seated on the load port 101, and the control unit 500 that controls components including the substrate supply unit 100, the stage 200, and the load port 101, and integrates data received from each component to generate integrated management data.

According to an embodiment, the stage 200 and the process chamber 300 may be operated in a vacuum pressure state, and the load port 101 may be operated in an atmospheric pressure state.

The control unit 500 may determine whether a get or put operation of a transfer robot 210 is properly performed by a sensing unit provided in the FOUP 400. The sensing unit may be electrically connected to the control unit 500 to transmit/receive electrical signals to/from each other.

The load port 101 may be coupled to the front end of the stage 200 to support the FOUP 400. A plurality of load ports 101 may be provided, and a FOUP 400 may be mounted on a top surface of each of the plurality of load ports 101. An adapter (not shown) electrically connected to the FOUP 400 may be provided on the top surface of each load port 101. The adapter is electrically coupled to a connector (not shown) provided under each FOUP 400, and power is supplied to the FOUPs 400 by the control of the control unit 500, by way of the adapter.

The stage 200 supports a plurality of process chambers 300 and may include the transfer robot 210. The stage 200 may be formed in a polygonal shape, and a plurality of process chambers 300 and a pair of load ports 101 may be provided on the sides of the polygon.

An unprocessed substrate and a processed substrate may be respectively loaded on a pair of load ports 101. The unprocessed substrate loaded on the load port 101 may be loaded (e.g., retrieved or picked up) by the transfer robot 210 and the transfer robot 210 may unload the unprocessed substrate to (e.g., into) the process chamber 300, or a processed substrate on which the process is completed and which is present in the process chamber 300 may be loaded by the transfer robot 210 and the transfer robot 210 may unload the processed substrate to the load port 101.

The transfer robot 210 may include a first robot arm 211 and a second robot arm 212 on an opposite side of the transfer robot 210 from the first robot arm 211. The transfer robot 210 may simultaneously transfer two substrates by including a pair of robot arms 211 and 212 on opposite sides from each other. For example, the transfer robot 210 may unload a substrate stored in the second robot arm 212 to another chamber, or load a substrate stored in another chamber to the second robot arm 212, while storing another substrate with the first robot arm 211. Conversely, the transfer robot 210 may unload a substrate stored in the first robot arm 211 to another chamber, or load a substrate stored in another chamber to the first robot arm 211, while storing another substrate with the second robot arm 212.

According to an embodiment, a process may be performed on a substrate in the process chamber 300. The process chamber 300 may be provided with a susceptor 310 on which a substrate is loaded. The process chamber 300 may be configured to perform various substrate processing operations. For example, the process chamber 300 may be an ashing chamber that removes photoresist, a chemical vapor deposition (CVD) chamber configured to deposit an insulating layer, or an etch chamber configured to etch apertures or openings in the insulating layer to form interconnect structures. Alternatively, the process chamber 300 may be a physical vapor deposition (PVD) chamber configured to deposit a barrier layer, or a PVD chamber configured to deposit a metal layer.

The FOUP 400 may accommodate a plurality of substrates therein to be detachably coupled to different semiconductor manufacturing equipment, so that the substrates may sequentially undergo different processes. Each of the FOUPs 400 may be mounted on the top surface of the load port 101.

The FOUP 400 according to the inventive concept may include a sensing unit for sensing a transfer path when the transfer robot 210 enters into and retreats from the FOUP 400. In addition, the FOUP 400 may be electrically connected to the adapter of the load port 101 to transmit the sensed transfer path data of the transfer robot 210 to the control unit 500. In addition, the entrance 110 serving as a passage between the stage 200 and the load port 101 may include a sensing unit for sensing the transfer path when the transfer robot 210 enters and retreats. In addition, a sensor positioned in the entrance 110 may be configured to measure a point in time when the entrance 110 is opened or closed. The sensor positioned in the entrance 110 may be configured to be electrically connected to the adapter of the load port 101 to transmit the sensed transfer path data and the opening or closing time point of the entrance 110 to the control unit 500.

According to an embodiment, the cooler 220 may be installed inside the stage 200 to cool the substrate on which the process has been completed in the process chamber 300. The cooler 220 is provided with a plurality of cooling spaces each capable of accommodating a substrate, and is configured to cool a plurality of substrates at a time. The cooler 220 may have a cooling unit for cooling the substrate on which the process has been completed. Various methods such as cooling by cooling water or cooling by using a thermoelectric element may be used as the cooling unit.

According to an embodiment, as shown in FIG. 2, the control unit 500 may be electrically and/or communicatively connected to the cooler 220, the transfer robot 210, the load port 101, the entrance 110, and the process chamber 300 to transmit/receive electrical signals to/from each other. The control unit 500 may control the semiconductor manufacturing equipment 10 by transmitting/receiving electrical signals to/from the cooler 220, the transfer robot 210, the load port 101, and the process chamber 300, which will be described in detail later.

In an embodiment, the control unit 500 may be implemented in hardware, firmware, software, or any combination thereof. For example, the control unit 500 may be a computing device such as a workstation computer, a desktop computer, a laptop computer, or a tablet computer. The control unit 500 may be a simple controller, a complex processor such as a microprocessor, a central processing unit (CPU), a graphical processing unit (GPU), or the like, a processor configured by software, dedicated hardware, or firmware. For example, the control unit 500 may be implemented by a general-purpose computer or application-specific hardware such as a digital signal processor (DSP), a field programmable gate array (FPGA), and an application specific integrated circuit (ASIC).

In an embodiment, the operation of the control unit 500 may be implemented as instructions stored on a machine-readable medium that may be read and executed by one or more processors. Here, the machine-readable medium may include any mechanism for storing and/or transmitting information in a form readable by a machine (e.g., a computing device). For example, machine-readable media may include read only memory (ROM), random access memory (RAM), magnetic disk storage media, optical storage media, flash memory devices, electrical, optical, acoustic, or other types of radio signals (e.g., carrier, infrared signal, digital signal, etc.) and any other signal.

The control unit 500 may be implemented with firmware, software, routine, and instructions for operating the semiconductor manufacturing equipment 10. For example, the control unit 500 may be implemented by software that receives data for feedback, generates a signal to operate the semiconductor manufacturing equipment 10, and performs a predetermined operation.

In an embodiment, an equipment front end module (EFEM) may be positioned between the stage 200 and the load port 110. The EFEM may include an end effector configured to transfer a substrate accommodated in the FOUP 400 to the stage 200, or to transfer a process-completed substrate from the stage 200 to the FOUP 400. The end effector may be an end effector of the transfer robot 210 and may therefore be operatively or functionally attached, connected, or coupled to the transfer robot 210. More than one end effector may be provide such that each end effector corresponds to a different one of the first and second robot arms 211 and 212.

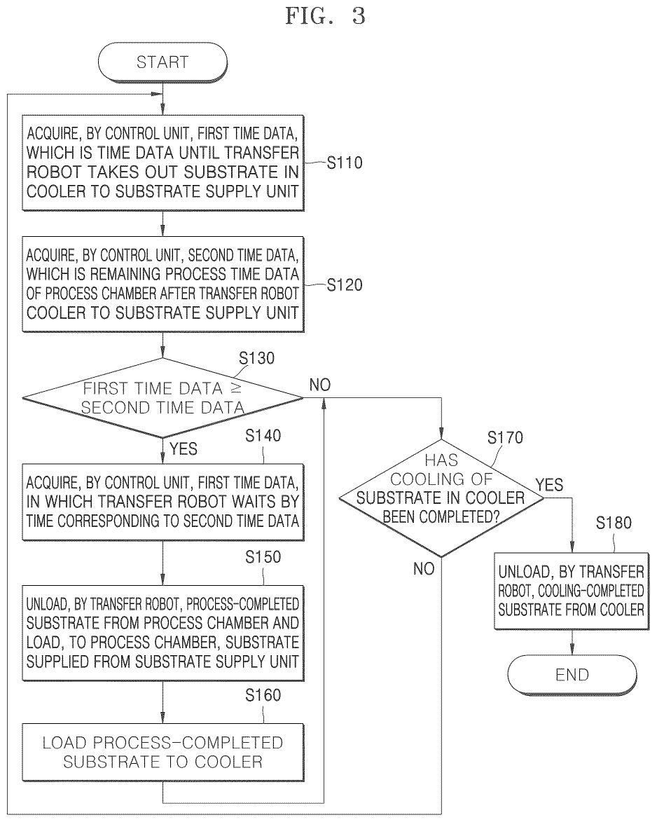

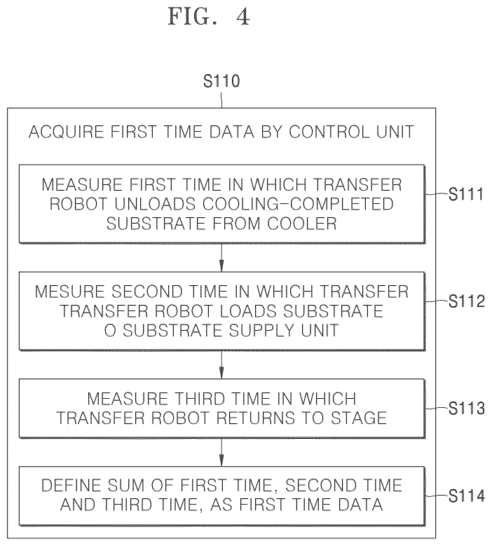

FIG. 3 is a flowchart illustrating a method of controlling semiconductor manufacturing equipment according to an embodiment, and FIG. 4 is a flowchart of a portion of the method of controlling the semiconductor manufacturing equipment shown in FIG. 3.

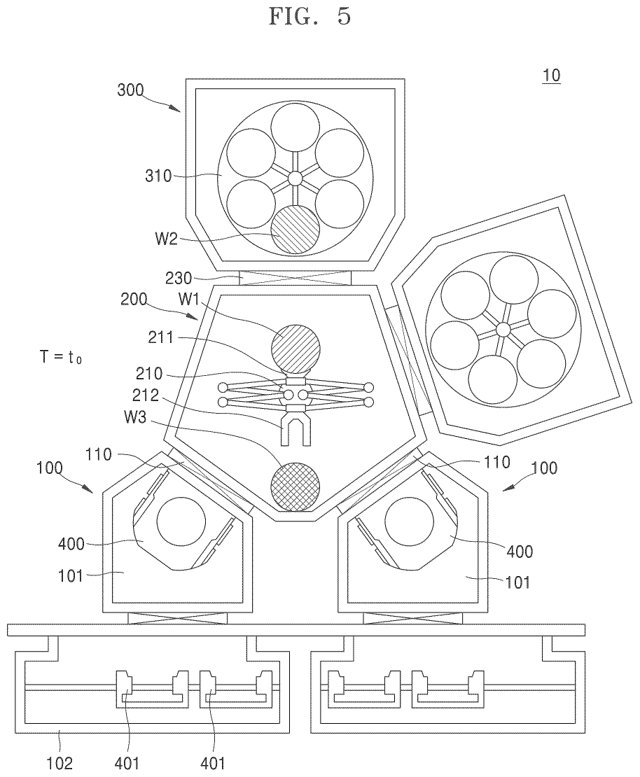

FIGS. 5 to 10 are diagrams sequentially illustrating a method of controlling semiconductor manufacturing equipment 10 according to an embodiment in time series order.

Hereinafter, for convenience of explanation, referring to FIGS. 5 to 10, with reference to FIGS. 3 and 4, the method of controlling semiconductor manufacturing equipment 10 is described.

Referring to FIG. 3, the method of controlling the semiconductor manufacturing equipment 10 may include an operation S110 of acquiring first time data, which is an amount of time taken for the transfer robot 210 to take out the substrate in the cooler 220 and place it in the substrate supply unit 100.

Specifically, the control unit 500 may acquire the first time data taken for the transfer robot 210 to take out the substrate in the cooler 220 to the substrate supply unit 100. A detailed description thereof will be made with reference to FIG. 4.

Referring to FIG. 5 together with FIG. 4, first, the first robot arm 211 of the transfer robot 210 may load (e.g., may have loaded thereon) a first substrate W1. The first substrate W1 is a substrate that has not been processed, and may be a substrate supplied from the FOUP 400 mounted on the load port 101.

The process chamber 300 may perform a process treatment on a second substrate W2 arranged in the process chamber 300, and the cooler 220 may perform a cooling process on a third substrate W3 arranged in the cooler 220.

The transfer robot 210 having the first substrate W1 loaded on the first robot arm 211 may be in a standby state in the stage 200. In the standby state, the control unit 500 transmits an electrical signal for performing a subsequent operation to the transfer robot 210. In addition, in the standby state, the transfer robot 210 may transmit information about a reference time point t₀ to the control unit 500 when the standby state is reached. The standby state refers to a state in which the transfer robot 210 loads, on the first robot arm 211, the first substrate W1, which is an unprocessed substrate, from the substrate supply unit 100 and waits on the stage 200 without loading any substrate on the second robot arm 212. The reference time t₀ may be defined as a time point when the transfer robot 210 reaches the standby state.

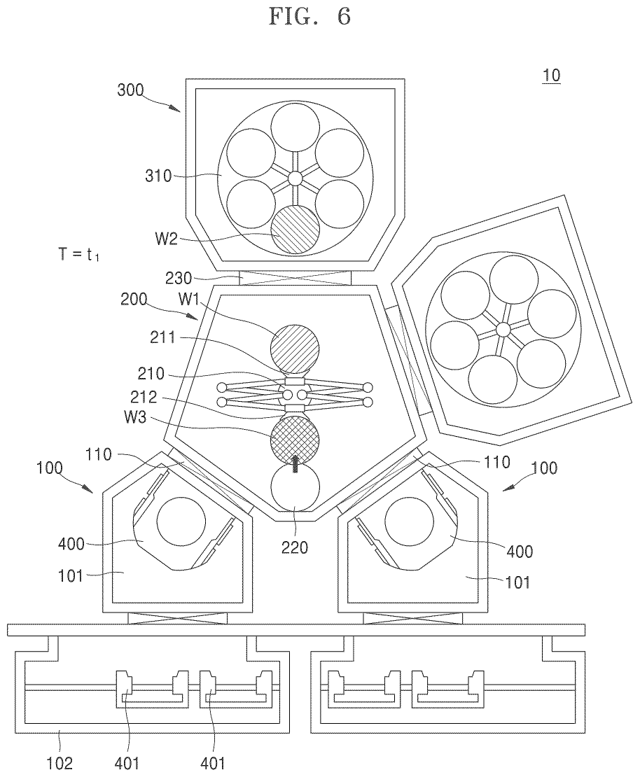

Referring to FIG. 6 together with FIG. 4, the operation S110 of acquiring the first time data by the control unit 500 may include an operation S111 of measuring a first time t₁ at which the transfer robot 210 loads the cooled third substrate W3 in the cooler 220.

The transfer robot 210 may load the third substrate W3 on which the cooling process is completed in the cooler 220. In this case, since the first substrate W1 is loaded on the first robot arm 211, the transfer robot 210 may load the third substrate W3 by inserting the second robot arm 212 into the cooler 220. The cooler 220 may include a sensing unit capable of sensing whether the cooling-completed processing substrate is unloaded from the entrance and sensing a time at which the processing substrate is taken out. In the disclosure, the feature that the substrate is taken out from a specific component has the same meaning as the feature that the substrate is unloaded from the specific component. Alternatively, the expression that the substrate is taken out from a specific structure may mean that the substrate is loaded onto a transfer robot from the specific structure. Likewise, the feature that the substrate is put into a specific component has the same meaning as the feature that the substrate is loaded to the specific component. Alternatively, the expression that the substrate is put into a specific structure may mean that the substrate is unloaded from a transfer robot and loaded into the specific structure.

The cooler 220 may measure the first time point t₁ at which the transfer robot 210 loads the cooled third substrate W3 (e.g., the time point at which the transfer robot 210 retrieves the cooled third substrate W3 from the cooler 220) and transmit information on the first time point t₁ to the control unit 500. The cooler 220 may include a cooling space capable of accommodating and cooling a substrate, and an entrance that is a space in which the substrate may enter/exit into/out of the cooling space. Specifically, the first time point t₁ may be defined as the time when the entrance of the cooler 220 is opened and the second robot arm 212 retrieves the third substrate W3, and then the entrance of the cooler 220 is closed. The cooler 220 may transmit information on the first time point t₁ when the entrance of the cooler 220 is closed to the control unit 500.

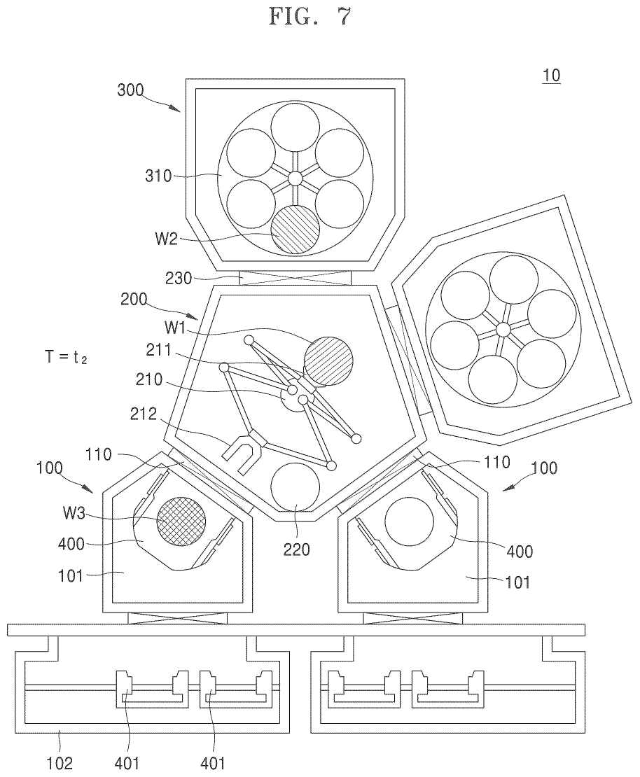

Referring to FIG. 7 together with FIG. 4, the operation S110 of acquiring the first time data by the control unit 500 may include an operation S112 of measuring the second time point t₂ of the transfer robot 210 unloading the third substrate W3 into the substrate supply unit 100.

The third substrate W3 is a substrate on which a cooling process has been completed in the cooler 220. The transfer robot 210 may unload the third substrate W3 on which the cooling process has been completed in the cooler 220 from the second robot arm 212 to the substrate supply unit 100. The transfer robot 210 may rotate so that the second robot arm 212 is aligned toward the entrance 110. Thereafter, the second robot arm 212 may extend toward the load port 101 and pass through the entrance 110, and unload the third substrate W3 into the FOUP 400 in the load port 101. A time point at which the entrance 110 closes after the third substrate W3 is seated in the FOUP 400 and the second robot arm 212 is retracted from the load port 101 may be defined as a second time point t₂. The entrance 110 may transmit, to the control unit 500, information on the second time point t₂ when the entrance 110 has been closed.

In other words, the second time point t₂ may also be defined as a time point at which the third substrate W3 is loaded into the load port 101 of the substrate supply unit 100 after the first time point t₁.

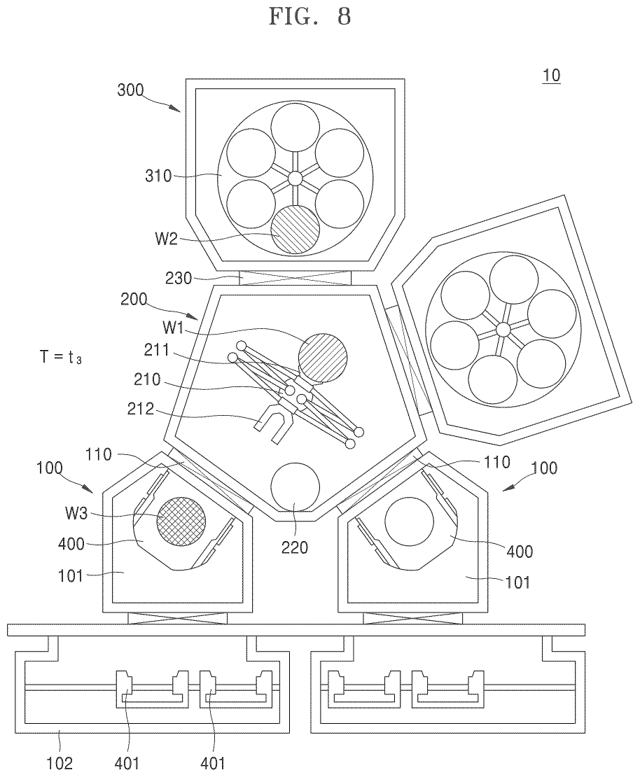

Referring to FIG. 8 together with FIG. 4, the operation S110 of acquiring the first time data by the control unit 500 may include an operation S113 of measuring a third time point t₃ for the transfer robot 210 to return to the stage 200.

As shown in FIG. 8, the entrance 110 may be closed, and the second robot arm 212 of the transfer robot 210 may return to the stage 200.

The transfer robot 210, having loaded the first substrate W1 onto the first robot arm 211, may return to a standby state within the stage 200 without loading any substrate onto the second robot arm 212. In the standby state, the transfer robot 210 may transmit information about a third time point t₃ to the control unit 500 when the standby state is reached. The standby state at the third time point t₃ refers to a state in which the transfer robot 210 loads, on the first robot arm 211, the first substrate W1, and waits on the stage 200 without loading any substrate on the second robot arm 212.

Thereafter, the operation S110 of acquiring the first time data by the control unit 500 may include an operation S114 of defining the sum of the received first time point t₁, second time point t₂, and third time point t₃ as first time data. The control unit 500 may be configured to obtain a sum of the first time t₁, the second time t₂, and the third time t₃ through arithmetic processing, define the sum as first time data, and then store the derived first time data in a memory.

According to an embodiment, the control unit 500 may have a reference time point t₀, a first time point t₁, a second time point t₂, and a third time point t₃ at specific times. Accordingly, the control unit 500 may be configured to obtain the sum of an amount of time from the reference time point t₀ to the first time point t₁, an amount of time from the first time point t₁ to the second time point t₂, and an amount of time from the second time point t₂ to the third time point t₃, and store time data for the sum of the derived times in the memory.

Referring back to FIG. 8 together with FIG. 3, the method of controlling the semiconductor manufacturing equipment 10 may include an operation S120 of the control unit 500 acquiring the second time data, which is remaining process time data of the process chamber 300, after the transfer robot 210 accommodates the substrate from the substrate supply unit 100.

The susceptor 310 of the process chamber 300 may provide a space for accommodating a plurality of substrates. The process chamber 300 is configured to perform a process with respect to each of the plurality of substrates. The process chamber 300 defines, as second time data, the least (e.g., minimum) remaining amount of process time of a substrate among the plurality of substrates under processing in the process chamber 300. In the disclosure, a substrate having the least remaining amount of process time in the process chamber 300 is defined as a second substrate W2. The process chamber 300 may be provided with a sensing unit for measuring amounts of remaining process times of a plurality of substrates in which processing is in progress. The process chamber 300 may define, as a second substrate W2, a substrate having the least remaining amount of process time among remaining amounts of process times of a plurality of substrates. Thereafter, the process chamber 300 is configured to transmit, to the control unit 500, the second time data, which is remaining amount of process time data of the second substrate W2.

Referring back to FIG. 8 together with FIG. 3, the method of controlling the semiconductor manufacturing equipment 10 may include an operation S130 of comparing the first time data with the second time data by the control unit 500. The first time data is the sum of the amount of time between the reference time point t₀ and the first time point t₁, the amount of time between the first time point t₁ and the second time point t₂, and the amount of time between the second time point t₂ and the third time point t₃, that is, the amount of time from the reference time point t₀ to the third time point t₃, which is the time in which the transfer robot 210 waits in the stage 200. The second time data includes information on remaining amount of process time of the second substrate W2.

Thereafter, when the first time data is greater than or equal to the second time data, the method of controlling the semiconductor manufacturing equipment 10 may include an operation S140 in which the transfer robot 210 waits for an amount of time corresponding to the second time data in the stage 200.

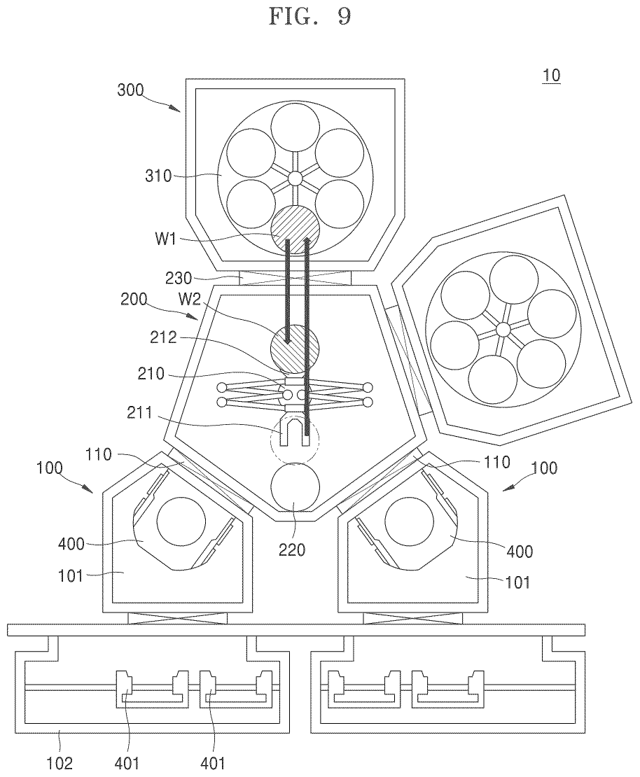

Thereafter, referring to FIG. 9 together with FIG. 3, the method of controlling the semiconductor manufacturing equipment 10 may include an operation S150 of retrieving the process-completed second substrate W2 from the process chamber 300 and loading the first substrate W1 supplied from the substrate supply unit 100 into the process chamber 300.

The second robot arm 212 of the transfer robot 210 may extend toward the process chamber 300 and pass through a process chamber entrance 230. The second robot arm 212 having passed through the process chamber entrance 230 retracts from the process chamber 300 after loading the process-completed second substrate W2. In addition, the transfer robot 210 may rotate by 180 degrees so that the first robot arm 211 opposite to the second robot arm 212 may extend toward the process chamber 300 and pass through the process chamber entrance 230. The first robot arm 211 having passed through the process chamber entrance 230 unloads the first substrate W1, which is an unprocessed substrate, into the process chamber 300 and then retracts from the process chamber 300.

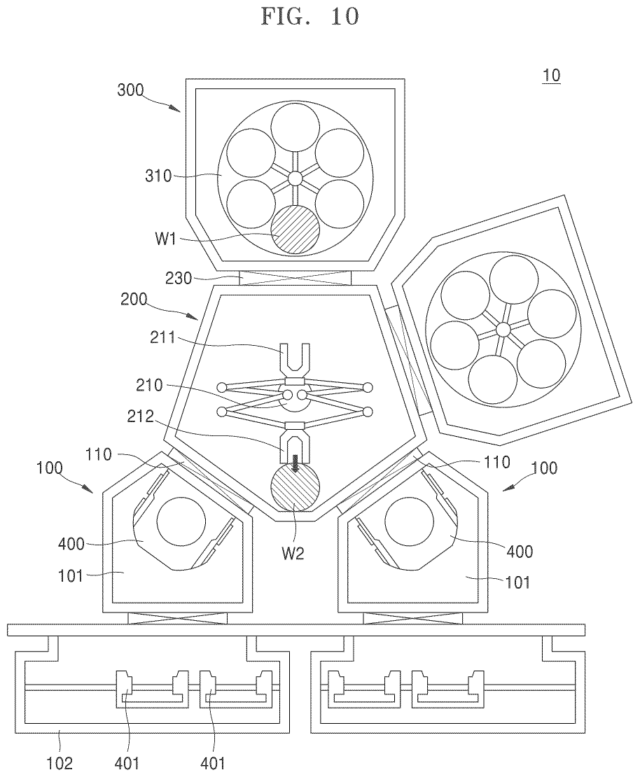

Thereafter, referring to FIG. 10 together with FIG. 3, the method of controlling the semiconductor manufacturing equipment 10 may include an operation S160 of unloading the process-completed second substrate W2 to the cooler 220. The second substrate W2 may be mounted in the cooler 220, and the cooler 220 may perform a cooling treatment on the completed second substrate W2.

Thereafter, the method of controlling the semiconductor manufacturing equipment 10 may include an operation S170 of determining whether cooling of the substrate of the cooler 220 has been completed. The detailed description thereof will be made in detail in the description of the case where the first time data is less than the second time data in the operation S130 of comparing the first time data with the second time data.

Hereinafter, in the operation S130 of comparing the first time data with the second time data, the method of controlling the semiconductor manufacturing equipment 10 when the first time data is less than the second time data will be described.

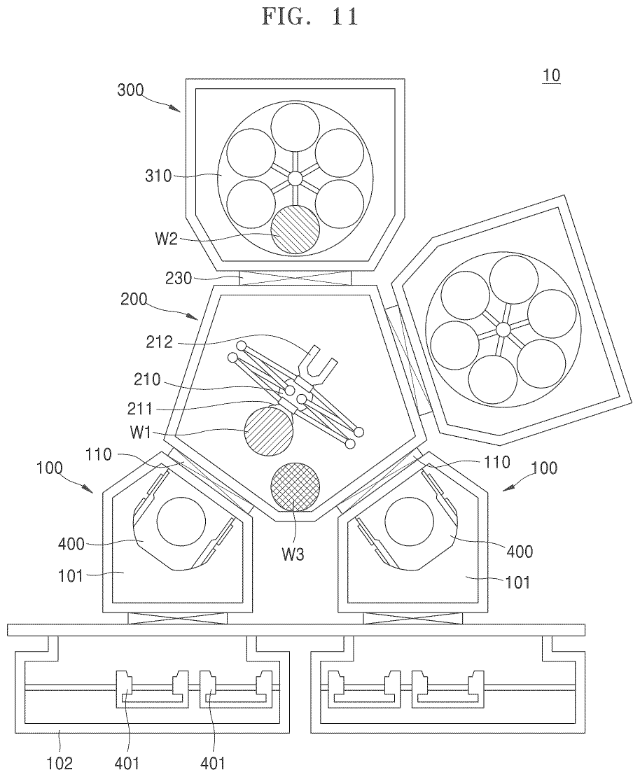

FIGS. 11 to 13 are diagrams sequentially illustrating a process of a portion of a method of controlling semiconductor manufacturing equipment 10 according to an embodiment in time series order.

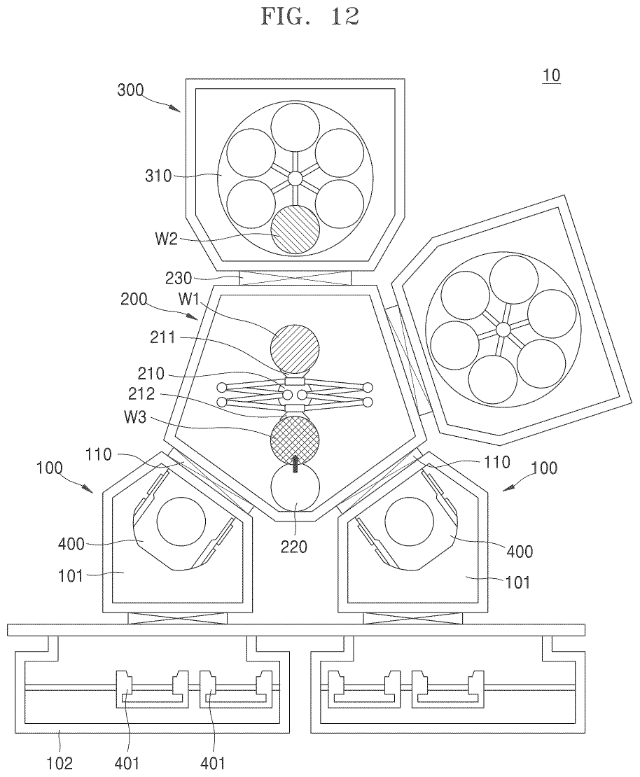

Referring to FIGS. 11 and 12 together with FIG. 3, when the first time data is less than the second time data, the method of controlling the semiconductor manufacturing equipment 10 may include an operation S170 of determining whether cooling for the third substrate in the cooler 220 has been completed. The cooler 220 may be configured to transmit, to the control unit 500, real-time information on whether the cooling process for the substrate located in the cooling space of the cooler 220 has been completed.

When the cooling of the third substrate W3 in the cooler 220 is completed, the method of controlling the semiconductor manufacturing equipment 10 may include an operation S180 of unloading the cooled third substrate W3 from the cooler 220 by the transfer robot 210. Since the first robot arm 211 of the transfer robot 210 is currently holding the first substrate W1, the second robot arm 212 is inserted into the cooler 220 to retrieve the third substrate W3.

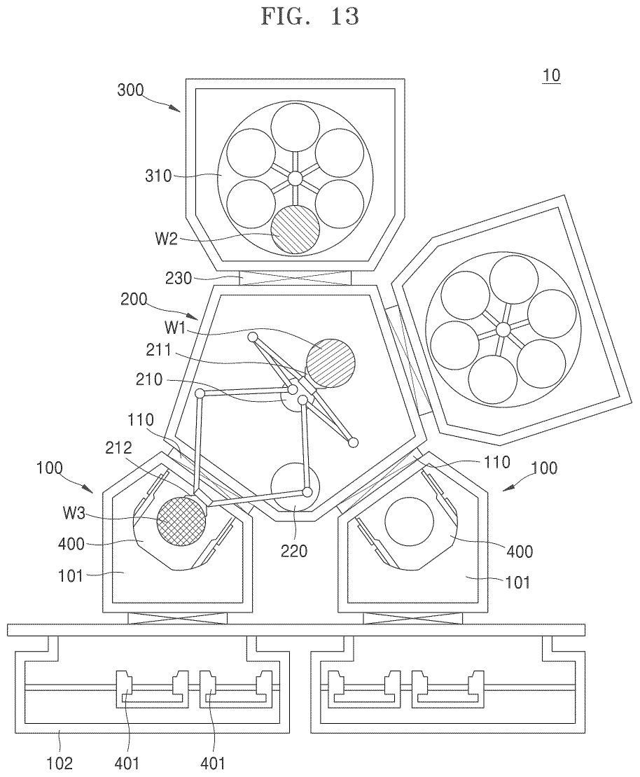

Thereafter, referring to FIG. 13, the transfer robot 210 may unload the third substrate W3 that has been cooled in the cooler 220 from the second robot arm 212 to the substrate supply unit 100. The transfer robot 210 may rotate so that the second robot arm 212 is aligned toward the entrance 110. Thereafter, the second robot arm 212 may extend toward the load port 101 and pass through the entrance 110, and unload the third substrate W3 into the FOUP 400 in the load port 101.

If the cooling of the substrate in the cooler 220 is not completed in operation S170, the method of controlling the semiconductor manufacturing equipment 10 returns to operation S110, and sequentially proceeds from operation S110.

Using conventional semiconductor manufacturing equipment, processing in the process chamber may be completed while the transfer robot is transferring a cooled substrate from the cooler to the supply unit. In this case, there may be an undesirable delay between the completion of the processing in the process chamber and the beginning of the subsequent processing in the process chamber, while the transfer robot transfers the cooled substrate to the supply unit.

Using semiconductor manufacturing equipment according to an example embodiment, a control unit 500 determines the amount of time it will take to transfer the cooled substrate from the cooler to the substrate supply unit 100. Then, the control unit 500 checks whether the ongoing processing in the process chamber 300 will be completed before the transfer robot 210 is finished transferring the cooled substrate. If the ongoing processing will be completed before the transfer robot 210 is finished (e.g., if the first time data is greater than or equal to the second time data as shown in S130 of FIG. 3), then the transfer robot 210 leaves the cooled substrate in the cooler 220 while it waits for the ongoing processing to be completed (e.g., S140 of FIG. 3). Then, once the ongoing processing is completed, the transfer robot 210 retrieves a process-completed substrate from the process chamber 300 and loads an unprocessed substrate into the process chamber 300 (e.g., S150 of FIG. 3). The transfer robot 210 then loads the process-completed substrate into the cooler 220 (e.g., S160 of FIG. 3). After the above-described transfer of substrates, the transfer robot 210 may then remove the cooled substrate from the cooler if cooling is finished.

According to an aspect of the inventive concept, a method of manufacturing a semiconductor device using semiconductor manufacturing equipment, in a state in which a first substrate is positioned in a substrate supply unit, a second substrate is being processed in a process chamber, and a third substrate is being cooled in a cooler, includes: acquiring, by a control unit, first time data and second time data, the first time data being an amount of time taken for a transfer robot to transfer the third substrate that is being cooled in the cooler to the substrate supply unit, and the second time data being an amount of time remaining before completion of a process performed on the second substrate by the process chamber; comparing the first time data with the second time data; and controlling the transfer robot based on the comparison of the first time data with the second time data.

The controlling of the transfer robot may include, when the first time data is greater than or equal to the second time data, transmitting a signal to the transfer robot to wait for an amount of time corresponding to the second time data, during which the transfer robot is configured to refrain from transferring any substrate.

The controlling of the transfer robot may further include, after the amount of time corresponding to the second time data has passed, transmitting a signal to the transfer robot to unload the second substrate on which the process has been completed from the process chamber and load the first substrate supplied from the substrate supply unit into the process chamber.

The controlling of the transfer robot may include, when the first time data is less than the second time data, transmitting a signal to the transfer robot to unload the cooled third substrate from the cooler at a time point when cooling of the first substrate has been completed.

The controlling of the transfer robot may include, when the signal is transmitted to the transfer robot, causing the transfer robot to unload the cooled third substrate from the cooler at the time point when cooling of the first substrate has been completed.

The controlling of the transfer robot may include, when the first time data is less than the second time data, comparing the first time data with the second time data again at a time point when cooling of the third substrate has not been completed.

According to an aspect of the inventive concept, a method of manufacturing a semiconductor device includes: positioning a first substrate in a substrate supply unit; performing a process on a second substrate positioned in a process chamber; cooling a third substrate positioned in a cooler; unloading the first substrate from the substrate supply unit using a transfer robot; and controlling the transfer robot to move at least one of the first substrate, the second substrate, and the third substrate by comparing first time data with second time data after the transfer robot receives the first substrate from the substrate supply unit, the first time data being an amount of time taken for the transfer robot to transfer the third substrate from the cooler to the substrate supply unit, and the second time data being an amount of time remaining before completion of the process performed on the second substrate in the process chamber.

The method may further include, when the first time data is greater than or equal to the second time data, transmitting a signal to the transfer robot to wait for an amount of time corresponding to the second time data, during which the transfer robot is configured to refrain from transferring any substrate.

The method may further include, after the amount of time corresponding to the second time data has passed, transmitting a signal to the transfer robot to unload the second substrate on which the process has been completed from the process chamber and load the first substrate supplied from the substrate supply unit into the process chamber.

The method may further include, when the first time data is less than the second time data, transmitting a signal to the transfer robot to unload the cooled third substrate from the cooler at a time point when cooling of the third substrate has been completed.

The method may further include, when the first time data is less than the second time data, comparing the first time data with the second time data again at a time point when cooling of the third substrate has not been completed.

The first time data may be an amount of time taken for the transfer robot, which has unloaded the first substrate from the substrate supply unit, to retrieve the third substrate that has been cooled within the cooler, to load the third substrate into the substrate supply unit, and to return to the stage.

The transfer robot may include a pair of robot arms on opposite sides of the transfer robot from each other.

The method may further include measuring the first time data, using the substrate supply unit, by measuring an amount of time taken for the transfer robot to unload the first substrate from the substrate supply unit.

The method may further include measuring the first time data, using the substrate supply unit, by measuring an amount of time taken for the transfer robot to load the first substrate from the substrate supply unit.

The method may further include measuring the first time data, using the cooler, by measuring an amount of time taken for the transfer robot to unload the third substrate from the cooler.

The above-described semiconductor manufacturing equipment according to an example embodiment may advantageously prevent a delay between completion of processing in the process chamber and the beginning of the subsequent processing in the process chamber.

While the inventive concept has been particularly shown and described with reference to embodiments thereof, it will be understood that various changes in form and details may be made therein without departing from the spirit and scope of the disclosure.

What is claimed is:

1. Semiconductor manufacturing equipment comprising:
a substrate supply unit to which a front opening unified pod (FOUP) is configured to be detachably coupled, wherein the FOUP is configured to accommodate a first substrate therein;
a process chamber configured to perform a process on a second substrate transferred from the substrate supply unit;
a stage provided between the process chamber and the substrate supply unit, the stage including a cooler and a transfer robot, the cooler being configured to cool a third substrate on which the process has been completed in the process chamber, the transfer robot being configured to transfer the first substrate, the second substrate, and the third substrate while moving in and out of the substrate supply unit, the process chamber, and the cooler; and
a control unit configured to control the transfer robot by comparing first time data with second time data after the transfer robot receives the first substrate from the substrate supply unit, the first time data being an amount of time taken for the transfer robot to transfer the third substrate from the cooler to the substrate supply unit, and the second time data being an amount of time remaining before completion of the process performed on the second substrate in the process chamber.

2. The semiconductor manufacturing equipment of claim 1, wherein the control unit is configured to, when the first time data is greater than or equal to the second time data, transmit a signal to the transfer robot to wait for an amount of time corresponding to the second time data, during which the transfer robot is configured to refrain from transferring any substrate.

3. The semiconductor manufacturing equipment of claim 2, wherein the control unit is configured to, after the amount of time corresponding to the second time data has passed, transmit a signal to the transfer robot to unload the second substrate on which the process has been completed from the process chamber and load the first substrate supplied from the substrate supply unit into the process chamber.

4. The semiconductor manufacturing equipment of claim 1, wherein the control unit is configured to, when the first time data is less than the second time data, transmit a signal to the transfer robot to unload the cooled third substrate from the cooler at a time point when cooling of the third substrate has been completed.

5. The semiconductor manufacturing equipment of claim 1, wherein the control unit is configured to, when the first time data is less than the second time data, compare the first time data with the second time data again at a time point when cooling of the third substrate has not been completed.

6. The semiconductor manufacturing equipment of claim 1, wherein the first time data is an amount of time taken for the transfer robot, which has unloaded the first substrate from the substrate supply unit, to retrieve the third substrate that has been cooled within the cooler, to load the third substrate into the substrate supply unit, and to return to the stage.

7. The semiconductor manufacturing equipment of claim 1, wherein the transfer robot comprises a pair of robot arms on opposite sides of the transfer robot from each other.

8. The semiconductor manufacturing equipment of claim 1, wherein the substrate supply unit is configured to measure an amount of time taken for the transfer robot to load the first substrate from the substrate supply unit, and
wherein the substrate supply unit is configured to transmit the measured amount of time to the control unit.

9. The semiconductor manufacturing equipment of claim 1, wherein the substrate supply unit is configured to measure an amount of time taken for the transfer robot to unload the first substrate from the substrate supply unit, and
wherein the substrate supply unit is configured to transmit the measured amount of time to the control unit.

10. The semiconductor manufacturing equipment of claim 1, wherein the cooler is configured to measure an amount of time taken for the transfer robot to unload the third substrate from the cooler, and
the cooler is configured to transmit the measured amount of time to the control unit.

11. Semiconductor manufacturing equipment comprising:
a substrate supply unit to which a front opening unified pod (FOUP) is configured to be detachably coupled, wherein the FOUP is configured to accommodate a first substrate therein;
a process chamber configured to perform a process on a second substrate transferred from the substrate supply unit;
a stage provided between the process chamber and the substrate supply unit;
a cooler within the stage, the cooler being configured to cool a third substrate on which the process has been completed in the process chamber;
a transfer robot configured to wait in the stage to transfer the first substrate, the second substrate, and the third substrate while moving in and out of the substrate supply, the process chamber, and the cooler; and
a control unit configured to control the transfer robot by comparing first time data with second time data after the transfer robot receives the first substrate from the substrate supply unit, the first time data being an amount of time taken for the transfer robot waiting in the stage to transfer the third substrate from the cooler to the substrate supply unit, and the second time data being an amount of time remaining before completion of the process performed on the second substrate in the process chamber.

12. The semiconductor manufacturing equipment of claim 11, wherein
the process chamber is configured to accommodate a plurality of the second substrates and perform the process with respect to each of the plurality of second substrates, and
the second time data is a minimum remaining amount of process time of the plurality of second substrates.

13. The semiconductor manufacturing equipment of claim 11, wherein the first time data is an amount of time taken for the transfer robot to retrieve the cooled third substrate from the cooler, to load the third substrate into the substrate supply unit, and to return to the stage.

14. The semiconductor manufacturing equipment of claim 11, wherein the control unit is configured to, when the first time data is greater than or equal to the second time data, transmit a signal to the transfer robot to wait in the stage without transferring any substrate for an amount of time corresponding to the second time data.

15. The semiconductor manufacturing equipment of claim 14, wherein the control unit is configured to, after the amount of time corresponding to the second time data has passed, transmit a signal to the transfer robot to unload the second substrate on which the process has been completed from the process chamber and load the first substrate supplied from the substrate supply unit into the process chamber.

16. The semiconductor manufacturing equipment of claim 11, wherein the control unit is configured to receive the first time data and the second time data in real time.

17. The semiconductor manufacturing equipment of claim 11, wherein the cooler is configured to cool each of a plurality of the third substrates.

18. The semiconductor manufacturing equipment of claim 11, wherein the process chamber is configured to transmit the second time data to the control unit.

19. Semiconductor manufacturing equipment comprising:
a substrate supply unit to which a front opening unified pod (FOUP) is configured to be detachably coupled, wherein the FOUP is configured to accommodate a first substrate therein;
a process chamber configured to perform a process on a second substrate transferred from the substrate supply unit;
a stage provided between the process chamber and the substrate supply unit;
a cooler within the stage, the cooler being configured to cool a third substrate on which the process has been completed in the process chamber;
a transfer robot configured to wait in the stage to transfer the first substrate, the second substrate, and the third substrate while moving in and out of the substrate supply unit, the process chamber, and the cooler; and
a control unit configured to control operation of the transfer robot by comparing first time data with second time data after the transfer robot receives the first substrate from the substrate supply unit,
wherein the first time data is an amount of time taken for the transfer robot waiting in the stage to retrieve the cooled third substrate from the cooler, load the third substrate into the substrate supply unit, and return to the stage,
wherein the second time data is an amount of time remaining before completion of the process performed on the second substrate in the process chamber,
wherein, when the first time data is greater than or equal to the second time data, the control unit is configured to transmit a signal to the transfer robot to wait for an amount of time corresponding to the second time data, during which the transfer robot refrains from transferring any substrate,
wherein, when the first time data is less than the second time data, the control unit is configured to transmit a signal to the transfer robot to unload the cooled third substrate from the cooler at a time point when cooling of the third substrate has been completed, and
wherein, when the first time data is less than the second time data and cooling of the third substrate has not been completed, the control unit is configured to compare the first time data with the second time data again.

20. The semiconductor manufacturing equipment of claim 19,
wherein the substrate supply unit is configured to measure an amount of time taken for the transfer robot to load the first substrate from the substrate supply unit and to transmit the measured amount of time to the control unit,
wherein the substrate supply unit is configured to measure an amount of time taken for the transfer robot to unload the first substrate from the substrate supply unit and to transmit the measured amount of time to the control unit, and
wherein the cooler is configured to measure an amount of time taken for the transfer robot to unload the third substrate from the cooler and to transmit the measured amount of time to the control unit.
